(19) United States
(12) Patent Application Publication
(10) Pub. No.: US 2006/0148133 A1
(43) Pub. Date: Jul. 6, 2006

(54) Method of forming a MEMS device

(75) Inventors: Thomas Kieran Nunan, Carlisle, MA (US); Timothy J. Brosnihan, Natick, MA (US)

Correspondence Address: Steven G. Saunders;Bromberg & Sunstein LLP, 125 Summer Street, Boston, MA, 02110-1618, US

(73) Assignee: Analog Devices, Inc.

(21) Appl. No.: 11/028,249

(22) Filed: Jan. 3, 2005

(51) Int. Cl. H01L 21/44

(52) U.S. Cl. 438/117

(57) ABSTRACT

A method of forming a MEMS device first releases structure, relative to a substrate, to form a space between the structure and the substrate. The process then adds material to the space between the structure and the substrate to substantially stabilize the structure relative to the substrate. Then, at some subsequent point, the method removes at least a portion of the material from the space to re-release the structure.

### FIELD OF THE INVENTION

The invention generally relates to MEMS devices and, more particularly, the invention relates to methods of forming MEMS devices.

### BACKGROUND OF THE INVENTION

Microelectromechanical systems (“MEMS,” hereinafter “MEMS devices”) are used in a wide variety of applications. For example, MEMS devices currently are implemented as microphones to convert audible signals to electrical signals, as gyroscopes to detect pitch angles of airplanes, and as accelerometers to selectively deploy air bags in automobiles. In simplified terms, such MEMS devices typically have a movable structure suspended from a substrate, and associated circuitry that both senses movement of the suspended structure and delivers the sensed movement data to one or more external devices (e.g., an external computer). The external device processes the sensed data to calculate the property being measured (e.g., pitch angle or acceleration).

As their name suggests, MEMS devices are very small. Consistent with this goal, the movable structures in a MEMS device are very small and thus, quite fragile. Undesirably, during production, these small structures can fracture very easily. Accordingly, for these and other reasons, MEMS production processes often form the structure as late in the manufacturing sequence as possible to reduce potential structure damage.

The production process for the widely distributed IMEMS accelerometer (distributed by Analog Devices, Inc. of Norwood Mass.) illustrates this point. In particular, IMEMS accelerometers have both circuitry and structure on a single die. To protect the structure during manufacture, production processes form the circuitry on the die before fully forming and releasing the structure.

Despite the apparent benefits of this solution, such a process has one drawback. In particular, this process requires very high temperatures to form the structure. Consequently, the previously formed circuitry must be able to withstand high temperatures without being damaged. The type of circuitry that can withstand such temperatures, however, is limited, thus potentially limiting the functionality and performance of such MEMS devices. Moreover, processes for releasing the MEMS structure also can be detrimental to the circuitry and thus, can be difficult to perform after a circuit processing is complete.

### SUMMARY OF THE INVENTION

In accordance with one aspect of the invention, a method of forming a MEMS device first releases structure, relative to a substrate, to form a space about at least a portion of the structure. The process then adds material to the space to substantially stabilize the structure relative to the substrate. Then, at some subsequent point, the method removes at least a portion of the material from the space to re-release the structure.

The method may form the barrier layer on the structure before adding the material to the space. The barrier layer also is between the structure and material after the material is added. In some embodiments, post-processing processes are performed before removing the material. The post-processing processes may include, among other things, forming circuitry or forming an in-situ cap. Moreover, in some embodiments, the structure is formed from at least one of silicon or polysilicon. In that case, among other things, the added material may be polysilicon. The material illustratively may be removed at temperatures below 400 degrees C. For example, the material may be removed by applying a dry gas phase etch to the material.

In accordance with another aspect of the invention, a method of forming a MEMS device provides a MEMS device having structure suspended from, and movable relative to, a substrate. The method then adds a first material to the space about the structure to substantially stabilize the structure relative to the substrate. The method subsequently removes at least a portion of the material from the space to re-release the structure.

In accordance with other aspects of the invention, a method provides a MEMS device having structure suspended from, and movable relative to, a substrate. Next, the method substantially immobilizes the structure relative to the substrate, and then modifies the MEMS device while the structure is substantially immobilized. Finally, after modifying the MEMS device, the method causes the structure to be movable relative to the substrate.

In illustrative embodiments, the structure forms a space between the substrate and the structure. In that case, the structure is substantially immobilized by adding material to the space between the structure and the substrate. This exemplary method consequently removes at least a portion of the added material from the space between the structure and the substrate when it causes the structure again to be movable (relative to the substrate).

### BRIEF DESCRIPTION OF THE DRAWINGS

The foregoing and advantages of the invention will be appreciated more fully from the following further description thereof with reference to the accompanying drawings wherein:

FIG. 1 schematically shows an exemplary MEMS device that can be formed in accordance with illustrative embodiments of the invention.

FIG. 2 shows a process of forming a MEMS device in accordance with illustrative embodiments of the invention.

FIG. 3 schematically shows a silicon-on-insulator wafer that may be used in illustrative embodiments of the invention.

FIG. 4 schematically shows a MEMS die that may be processed in illustrative embodiments of the invention as discussed with regard to step 200 of FIG. 2.

FIG. 5 schematically shows an oxidized MEMS die as discussed with regard to step 202 of FIG. 2.

FIG. 6 schematically shows the addition of a sacrificial material to a MEMS die as discussed with regard to step 204 of FIG. 2.

FIG. 7 schematically shows an additional oxidization layer as discussed with regard to step 206 of FIG. 2.

FIG. 8 schematically shows the addition of cap material to the MEMS die as discussed with regard to step 208 of FIG. 2.

FIG. 9 schematically shows the addition of yet another oxidation layer as discussed with regard to step 210 of FIG. 2.

FIG. 10 schematically shows the addition of contacts to the MEMS die as discussed with regard to step 212 of FIG. 2.

FIG. 11 schematically shows the removal the sacrificial material from the MEMS die as discussed with regard to step 214 of FIG. 2.

FIG. 12 schematically shows a plan view of the MEMS die as discussed with regard to step 214.

FIG. 13 schematically shows the addition of a seal to the MEMS die as discussed with regard to step 204 of FIG. 2.

### DESCRIPTION OF ILLUSTRATIVE EMBODIMENTS

In illustrative embodiments, a released MEMS device is filled with a stabilizing material to substantially stabilize its movable structure. While stabilized, the MEMS device may be further processed. Conventional processes can subsequently remove the stabilizing material in a manner that does not adversely impact other components of the MEMS device. Details of illustrative embodiments are discussed below.

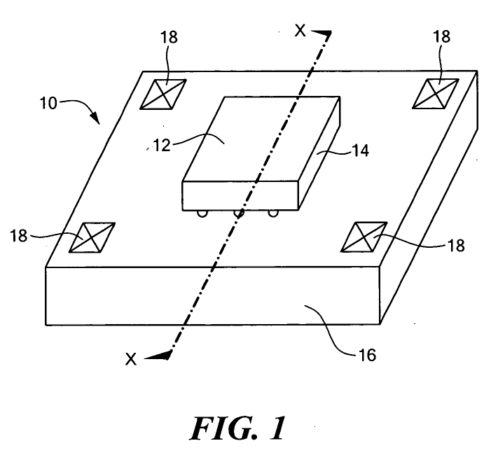

FIG. 1 schematically shows an exemplary MEMS system 10 that can be formed in accordance with illustrative embodiments of the invention. The MEMS system 10 includes a packaged MEMS device 12 having a die 13 (shown in cross-section in subsequent figures and also referred to as “MEMS device 13”) within a conventional ceramic package 14. The package 14 is coupled with a circuit board 16 having interconnects 18 to electrically communicate with an external device, such as a computer.

The packaged MEMS device 12 may implement any conventionally known functionality commonly implemented on a MEMS device, such as an inertial sensor. For example, the packaged MEMS device 12 may be a gyroscope or an accelerometer. Exemplary MEMS gyroscopes are discussed in greater detail in U.S. Pat. No. 6,505,511, which is assigned to Analog Devices, Inc. of Norwood, Mass. Exemplary MEMS accelerometers are discussed in greater detail in U.S. Pat. No. 5,939,633, which also is assigned to Analog Devices, Inc. of Norwood, Mass. The disclosures of U.S. Pat. Nos. 5,939,633 and 6,505,511 are incorporated herein, in their entireties, by reference.

Although the packaged MEMS device 12 is discussed above as an inertial sensor, principles of illustrative embodiments can apply to other MEMS devices, such as pressure sensors and microphones. Accordingly, discussion of an inertial sensor is exemplary and not intended to limit the scope of various embodiments of the invention.

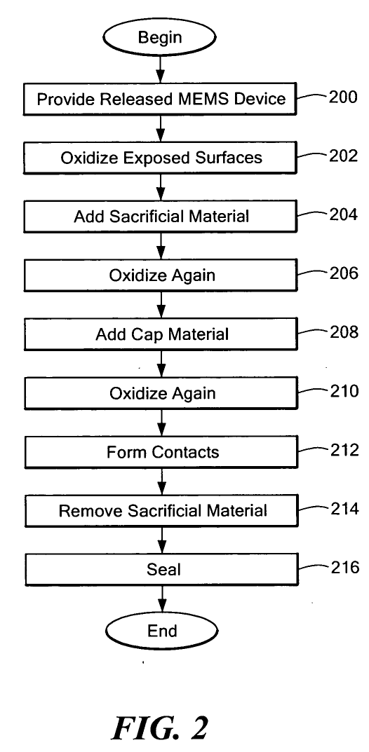

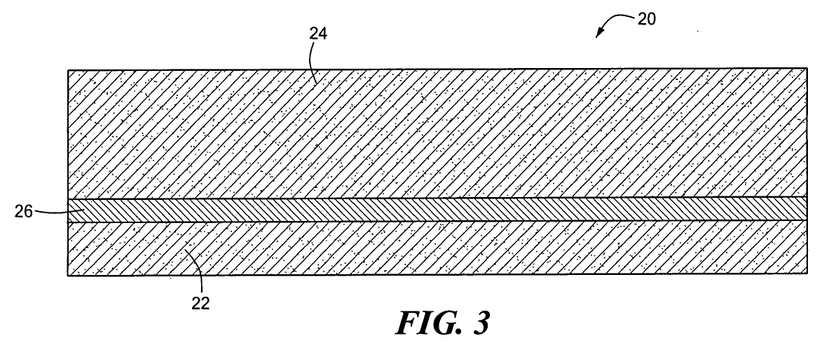

FIG. 2 shows a process of forming a MEMS device, such as the MEMS die 13 within the package 14 shown in FIG. 1, in accordance with illustrative embodiments of the invention. FIGS. 3-13 illustrate the MEMS die 13 at various stages of development discussed with regard to FIG. 2.

The process begins at step 200, in which a released MEMS device 13 is provided. A number of different processes may be used to form the released MEMS device 13. For example, conventional surface micromachining (“SMM”) techniques may form the released MEMS device 13. As known by those skilled in the art, surface micromachining techniques build material layers on top of a substrate using additive and subtractive processes. As a further example, conventional SCREAM processes can form the MEMS device 13. SCREAM is the acronym for “single crystal reactive etching and metallization” processes, developed at Cornell University in 1993.

In various embodiments, however, a combination of SMM and silicon-on-insulator (“SOI”) processes form the released MEMS device 13. FIG. 3 schematically shows a cross-sectional view of an exemplary SOI wafer 20 that can form the basis of the MEMS device 13. The SOI wafer 20 has a silicon handle layer 22, a silicon device layer 24 for forming the movable structure that is suspended from the handle layer 22, and an insulator layer 26 between the device and handle layers 24 and 22.

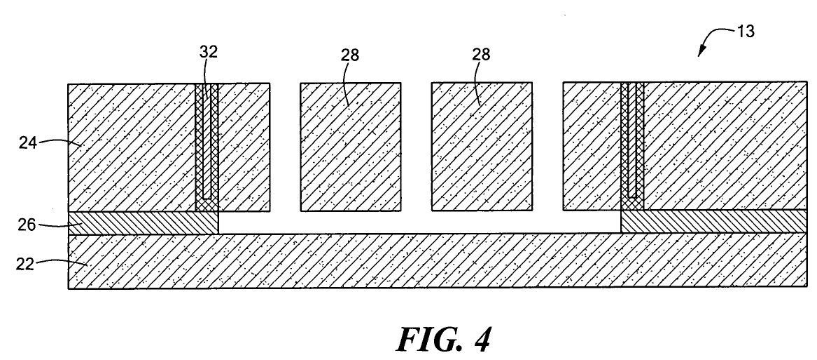

FIG. 4 schematically shows the released MEMS device 13, which was formed using an SOI wafer 20. As suggested above, the MEMS device 13 illustratively is a die (also referred to as “die 13”) having movable structure 28 (i.e., portions of the device layer 24) suspended above a substrate 22 (i.e., the handle layer 22). The device layer 24 also may have a nitride lined isolation trench 32 filled with polysilicon. The isolation trench 32 electrically isolates yet to be formed circuitry from the structure 28. Some embodiments, however, do not form circuitry on the die 13 and thus, do not require the isolation trench 32.

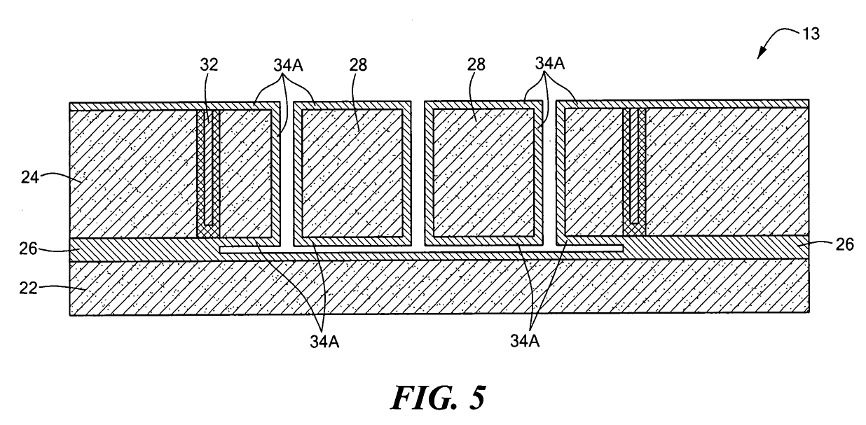

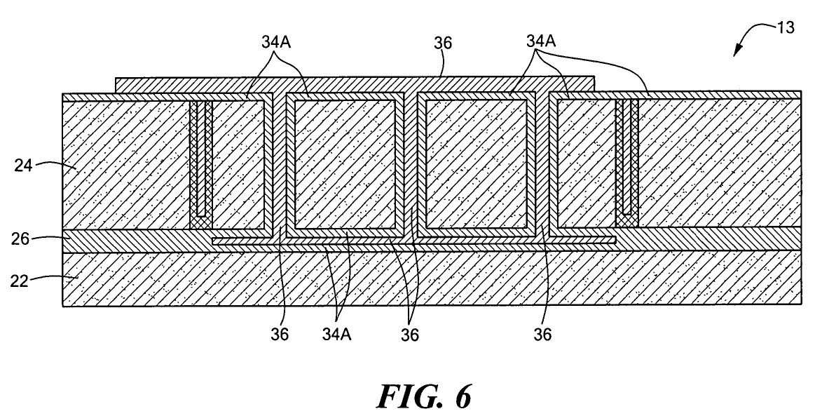

The process continues to step 202, in which the surfaces of the device layer 24 exposed to the atmosphere are oxidized (see FIG. 5). In illustrative embodiments, this step forms an oxide layer 34A having a thickness of about 1000 Angstroms. The process then may add sacrificial material 36 to at least some of the spaces in the die 13 to substantially immobilize the structure 28 (step 204, see FIG. 6). The spaces include those between the different stationary and movable parts of the die 13. For example, the spaces, which are about at least a portion of the structure 28, may be between the structure 28 and the substrate 22, or between the structure 28 and some other stationary portion (e.g., a fixed actuation finger, not shown).

In illustrative embodiments, the sacrificial material 36 is deposited in all spaces (i.e., around and below the structure 28), thus essentially transforming the die 13 into a substantially solid block of various materials. The sacrificial material 36 also may extend to a contiguous area on the top surface of the die 13. In illustrative embodiments, this extra sacrificial material 36 acts as a spacer and has a thickness of about 1 micron. Although contiguous, in some embodiments, the sacrificial material 36 may include a plurality of non-contiguous portions, or may not fill all spaces of the die 13.

In illustrative embodiments, the sacrificial material 36 is a sublime material, which changes from a solid state to a gaseous state without going through an intermediate liquid stage. In the embodiments shown, the sacrificial material 36 is polysilicon. Accordingly, the oxide layer 34A formed by step 202 acts as a barrier layer between the underlying structure 28 and the sacrificial material 36. Stated another way, the oxide layer 34A separates the silicon forming the structure 28 from the sacrificial material 36. Accordingly, the oxide layer 34A ensures that the underlying structure is not removed or otherwise contacted when the sacrificial material 36 is removed (discussed below). Of course, alternative embodiments may use other sacrificial materials, such as waxes or polymers.

At this point in the process, the structure 28 of the die 13 is substantially immobile. Accordingly, the die 13 may be subjected to various post processing processes. Among others, those processes may include the following:
forming circuitry to the device layer 24,
adding a ground plane electrode to the die 13,
depositing an in-situ cap on the die 13,
adding more MEMS structures,
adding assembly features, such as flip chip landing sites, bump bonds, and other similar items,
adding a metal interconnect (e.g., a floating metal/oxide bridge) across the sacrificial material 36 to electrically connect the structure 28. This bridge remains in place after the sacrificial material 36 is removed to provide an electrical connection to the structure 28.

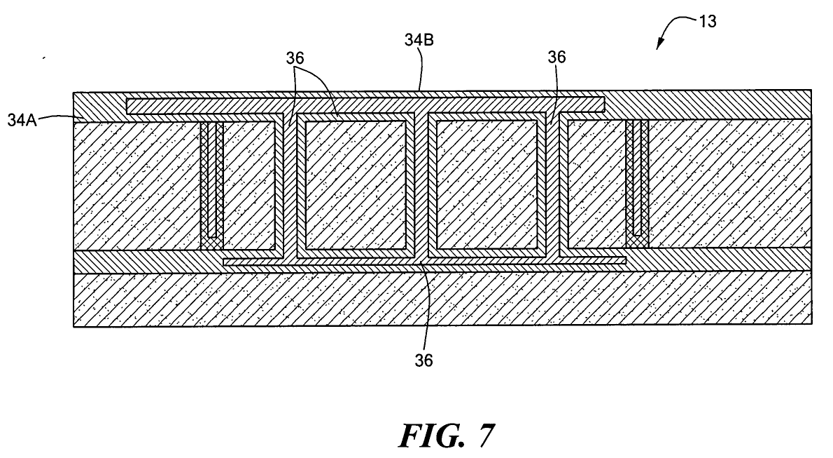

The circuitry illustratively is added to a portion that is isolated from the MEMS structure 28 by the nitride lined trench 32. The remaining steps of FIG. 2, however, discuss forming an in-situ cap and sealing the overall die 13. To those ends, the die 13 is oxidized again to form another 1000 Angstrom oxide layer 34B on the top surface of the spacer portion of the sacrificial material 36 (step 206). As shown in FIG. 7, the existing oxide layer 34A consequently thickens to merge smoothly into this new oxide layer 34B. This portion of the top surface of the die 13 thus is substantially planar at this point in the process.

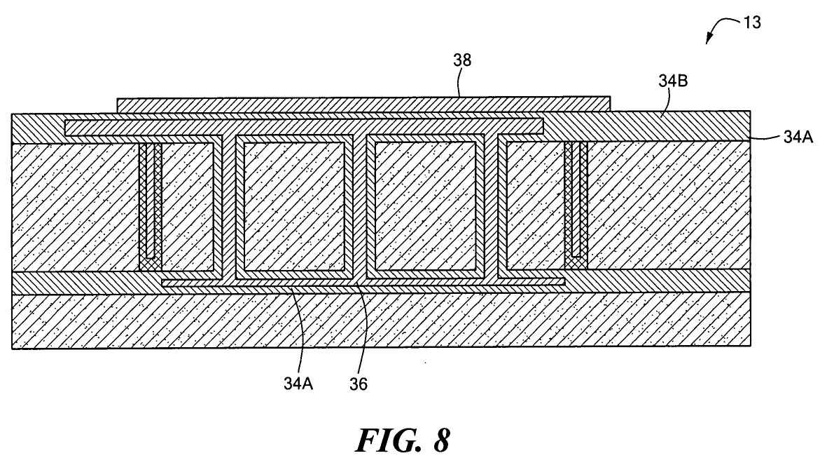

The process continues to step 208, in which cap material 38 is added to the top surface of the die 13 to form an in-situ cap (also identified by reference number 38). Specifically, as shown in FIG. 8, conventional processes deposit and pattern polysilicon to the oxide layer 34B on the top surface of the die 13. This deposited polysilicon layer illustratively has a thickness of about one micron.

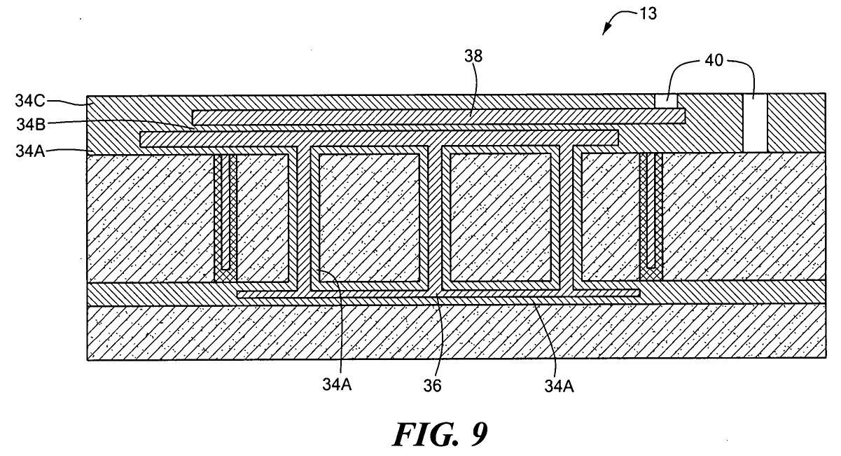

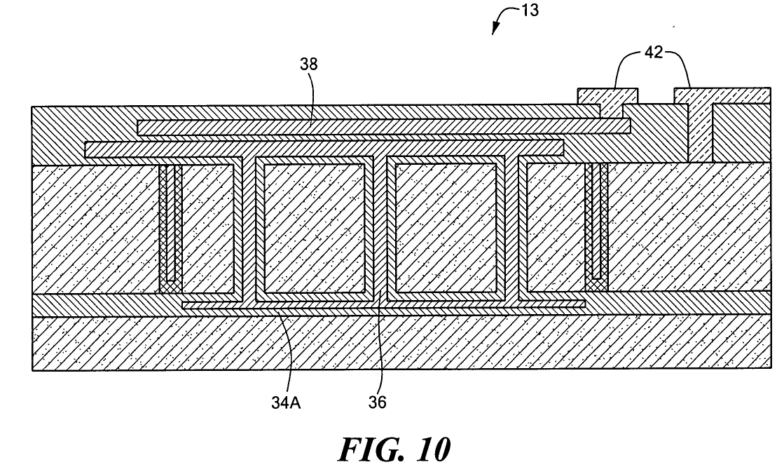

As shown in FIG. 9, the process again oxidizes the top surface of the die 13 to form yet another smooth surface (step 210). This oxide forms a third oxide layer 34C. To that end, illustrative embodiments deposit and pattern pre-metal dielectric comprising 0.5 micron thick BPSG. A trench 40 then is formed in the oxide layers 34A-34C to permit electrical contact with the cap and other conductors. Conventional metallization processes then may form metal contacts 42 to permit electrical interconnection (step 212 and FIG. 10).

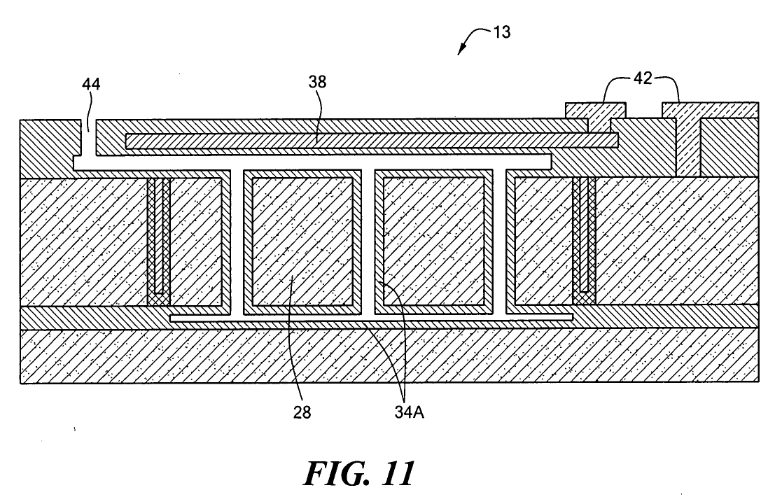

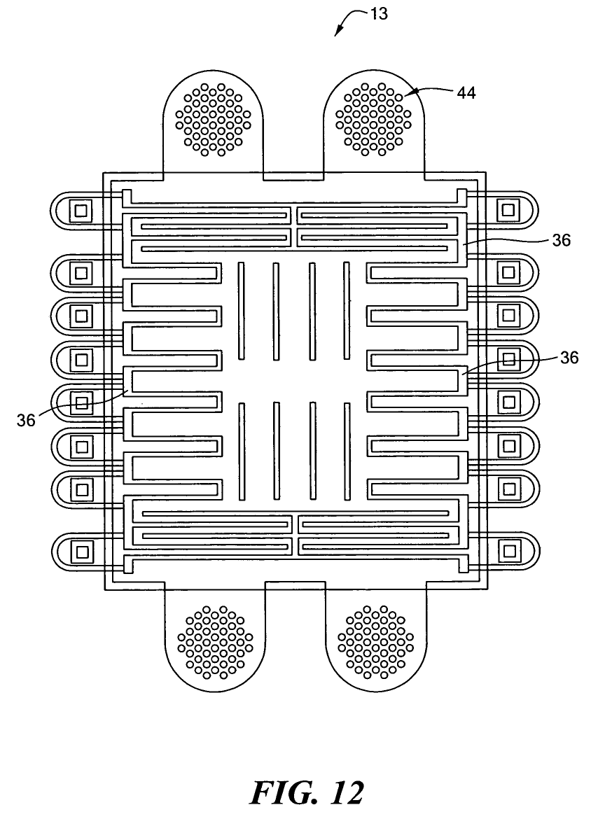

After post-processing steps are completed (i.e., in this case, the in-situ cap is formed), the sacrificial material 36 may be removed, thus re-releasing the structure 28 (step 214). Accordingly, this space restores the spaces occupied by the sacrificial material 36, thus permitting the structure 28 to move again relative to the substrate 22. To those ends, as shown in FIG. 11, a plurality of etch access holes 44 may be formed through the oxide layers 34B and 34C to contact the sacrificial polysilicon 36. The plurality of etch access holes 44 are shown in greater detail in FIG. 12, which shows a plan view of the die 13 just before the sacrificial material 36 is removed. This view of FIG. 12 shows an array of etch access holes 44, as well as the sacrificial material 36 between the suspended structure 28 and stationary die portions. The oxide and cap layers 34B and 34C and 38 are transparent (i.e., not shown) in FIG. 12 to show the sacrificial material 36.

In illustrative embodiments, a low temperature process removes the sacrificial material 36. If the die 13 includes circuitry, then the low temperature processes should be performed at a temperature that should not adversely affect the circuitry. For example, if temperatures above about 400 degrees C. could adversely affect circuitry, then such processes should be less than about 400 degrees C. In the case of polysilicon, a dry gas phase etch using xenon difluoride should suffice. As known by those in the art, this dry phase gas phase etch process can be performed at room temperature. Higher temperatures may be used, however, to improve processing. Such higher temperatures illustratively are lower than some determined maximum that could impact other components (e.g., lower than 400 degrees C.).

An optional step of removing some of the oxide could be performed, depending upon a number of factors, including the temperature required to remove the oxide and circuitry sensitivity.

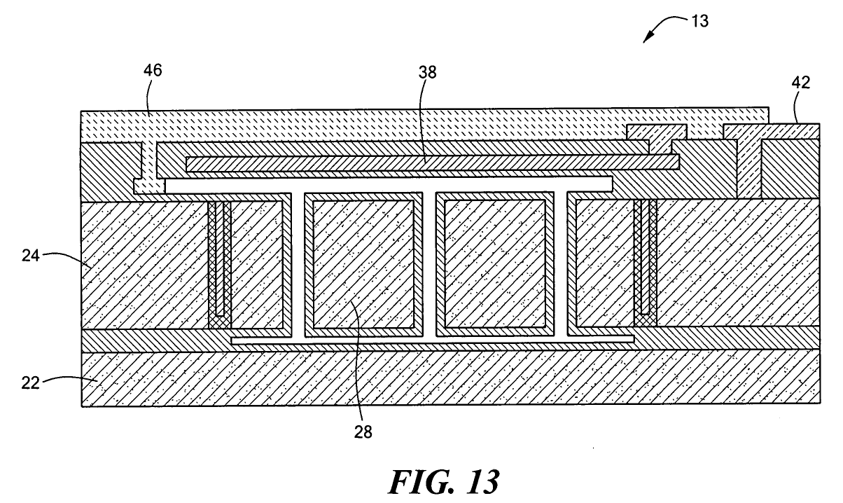

The process then concludes at step 216, in which the process seals the structure 28 within the die 13. To that end, as shown in FIG. 13, illustrative embodiments deposit and pattern an oxide nitride stack 46.

The die 13 produced by this process then may be packaged in a conventional manner. As suggested above, the die 13 may be packaged in a conventional ceramic package 14. Due to its in-situ cap 38, however, it may be packaged in other types of packages, such as plastic or premolded packages.

Accordingly, illustrative embodiments permit a MEMS die to be post-processed after the structure is released. For example, the die 13 may have high performance circuitry, which was not practical in prior art high temperature fabrication processes. Consequently, embodiments should deliver improved performance and facilitate the fabrication process.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a MEMS device, the method comprising:
releasing structure relative to a substrate, releasing forming a space about at least a portion of the structure;
adding material to the space, the material substantially stabilizing the structure relative to the substrate; and
removing at least a portion of the material from the space to re-release the structure.

2. The method as defined by claim 1 further including forming a barrier layer on the structure before adding the material to the space, the barrier layer being between the structure and material after the material is added.

3. The method as defined by claim 1 wherein the structure is formed from at least one of silicon or polysilicon, the added material being polysilicon.

4. The method as defined by claim 1 further including performing post-processing processes before removing the material.

5. The method as defined by claim 4 wherein post-processing includes forming circuitry.

6. The method as defined by claim 4 wherein post-processing includes forming an in-situ cap.

7. The method as defined by claim 1 wherein removing includes a process performed at a temperature below 400 degrees C.

8. The method as defined by claim 1 wherein removing includes applying a dry gas phase etch to the material.

9. The device formed according to the process defined by claim 1.

10. A method of forming a MEMS device, the method comprising:
providing a MEMS device having structure suspended from a substrate, the structure being movable relative to the substrate and forming a space;
adding first material to the space, the material substantially stabilizing the structure relative to the substrate; and
removing at least a portion of the material from the space to re-release the structure.

11. The method as defined by claim 10 further including performing post-processing processes before removing the material.

12. The method as defined by claim 10 wherein the structure includes silicon, the first material also including silicon.

13. The method as defined by claim 10 wherein removing includes applying a dry gas phase etch to the material.

14. A method comprising:
providing a MEMS device having structure suspended from a substrate, the structure being movable relative to the substrate;
substantially immobilizing the structure relative to the substrate;
modifying the MEMS device while the structure is substantially immobilized; and
after modifying the MEMS device, causing the structure to be movable relative to the substrate.

15. The method as defined by claim 14 wherein the structure forms a space between the substrate and the structure, further wherein substantially immobilizing comprises adding material to the space between the structure and the substrate.

16. The method as defined by claim 15 wherein the structure comprises silicon or polysilicon, the added material being polysilicon.

17. The method as defined by claim 15 wherein causing comprises removing at least a portion of the added material from the space between the structure and the substrate.

18. The method as defined by claim 14 wherein substantially immobilizing comprises forming a barrier layer on the structure.

19. The method as defined by claim 14 wherein modifying comprises performing post-processing processes.

20. The method as defined by claim 19 wherein performing post-processing processes comprises at least one of forming circuitry that cooperates with the structure, adding a cap, adding additional MEMS structure, adding an interconnect to the structure.
